(19) United States
(12) Patent Application Publication
(10) Pub. No.: US 2025/0192005 A1
(43) Pub. Date: Jun. 12, 2025

(54) SEMICONDUCTOR DEVICES INCLUDING ROUNDED COMPONENTS AND RELATED MANUFACTURING METHODS

(71) Applicant: Infineon Technologies AG, Neubiberg (DE)

(72) Inventors: Rainer Markus SCHALLER, Aichen (DE); Volker STRUTZ, Tegernheim (DE); Chin Yong NEO, Singapore (SG); Chan Whai KAN, Singapore (SG); Shao Ping WAN, Singapore (SG)

(21) Appl. No.: 18/974,971

(22) Filed: Dec. 10, 2024

(30) Foreign Application Priority Data
Dec. 11, 2023 (DE) 102023212490.4

(51) Int. Cl. H01L 23/495; G01R 33/00; H01L 21/304; H01L 21/3065; H01L 21/48; H01L 23/00; H01L 23/13

(52) U.S. Cl. CPC H01L 23/49558; H01L 21/3043; H01L 21/3065; H01L 21/4828; H01L 21/4842; H01L 23/13; H01L 24/29; H01L 24/32; H01L 24/94; G01R 33/0047; H01L 2224/29553; H01L 2224/32245; H01L 2224/94; H01L 2924/182

(57) ABSTRACT

A semiconductor device includes an electrically conductive carrier and a semiconductor chip arranged over a first portion of the carrier. The semiconductor device further includes a dielectric material arranged between the first portion of the carrier and the semiconductor chip, wherein the dielectric material galvanically isolates the first portion of the carrier and the semiconductor chip. At least one of the first portion of the carrier or the semiconductor chip includes at least one of a rounded corner or a rounded edge.

### CROSS-REFERENCE TO RELATED APPLICATION

This application claims priority to Germany Patent Application No. 102023212490.4filed on Dec. 11, 2023, the content of which is incorporated by reference herein in its entirety.

### TECHNICAL FIELD

The present disclosure relates to semiconductor devices including rounded components and methods for manufacturing such semiconductor devices.

### BACKGROUND

In semiconductor devices high electrical voltage differences may occur between individual device components during an operation of the device. For example, increased electrical potential differences may occur in a current sensor device between a current rail and a sensor chip arranged above the current rail. Depending on material properties and a relative positioning of the device components, increased voltage differences may result in high electric field stress in certain spatial areas of the device. The high electric field stress may cause electrical aging of device components and degradation of the device, which in the worst case may result in device failure. Manufacturers and developers of semiconductor devices are constantly striving to improve their products. In light of the above, it may be of particular interest to extend durability of semiconductor devices and to ensure their continued safe operation.

### SUMMARY

An aspect of the present disclosure relates to a semiconductor device. The semiconductor device includes an electrically conductive carrier and a semiconductor chip arranged over a first portion of the carrier. The semiconductor device further includes a dielectric material arranged between the first portion of the carrier and the semiconductor chip, wherein the dielectric material galvanically isolates the first portion of the carrier and the semiconductor chip. At least one of the first portion of the carrier or the semiconductor chip includes at least one of a rounded corner or a rounded edge.

A further aspect of the present disclosure relates to a method for manufacturing a semiconductor device. The method includes an act of forming at least one of a rounded corner or a rounded edge of at least one of a first portion of an electrically conductive carrier or a semiconductor chip. The method further includes an act of arranging a dielectric material over the first portion of the carrier. The method further includes an act of arranging the semiconductor chip over the dielectric material, wherein the dielectric material galvanically isolates the first portion of the carrier and the semiconductor chip.

### BRIEF DESCRIPTION OF THE DRAWINGS

Devices and methods in accordance with the disclosure are described in more detail below based on the drawings. Similar reference numerals may designate corresponding similar parts. The technical features of the various illustrated examples may be combined, provided they are not mutually exclusive, and/or may be selectively omitted if not described as being necessarily required.

FIG. 1 schematically illustrates a cross sectional side view of a semiconductor device 100, in accordance with the disclosure.

FIG. 2 schematically illustrates a cross sectional side view of a semiconductor device 200, in accordance with the disclosure.

FIG. 3 illustrates a flowchart of a method for manufacturing a semiconductor device, in accordance with the disclosure.

FIGS. 4A to 4F schematically illustrating a method for manufacturing a semiconductor device, in accordance with the disclosure.

FIGS. 5A to 5C schematically illustrating a method for manufacturing a semiconductor device, in accordance with the disclosure.

FIGS. 6A to 6C schematically illustrating a method for manufacturing a semiconductor device, in accordance with the disclosure.

### DETAILED DESCRIPTION

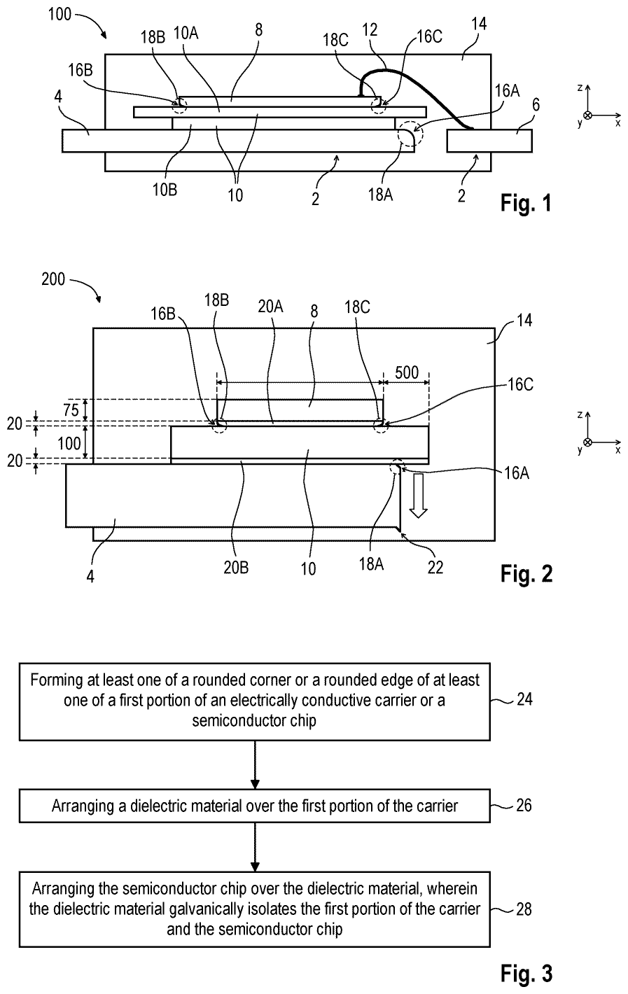

The semiconductor device 100 of FIG. 1 may include an electrically conductive carrier 2 with a first portion 4 and a second portion 6. A semiconductor chip 8 may be arranged over the first portion 4 of the carrier 2. The semiconductor device 100 may further include a dielectric material 10 arranged between the first portion 4 of the carrier 2 and the semiconductor chip 8. The dielectric material 10 may be configured to galvanically isolate the first portion 4 of the carrier 2 and the semiconductor chip 8. The semiconductor chip 8 may be electrically connected to the second portion 6 of the carrier 2 by an electrical connection element 12. The components of the semiconductor device 100 may be at least partially encapsulated in an encapsulation material 14. At least one of the first portion 4 of the carrier 2 or the semiconductor chip 8 may include at least one of a rounded corner or a rounded edge 16.

In the illustrated example, the electrically conductive carrier 2 may be a leadframe. The leadframe may be made of metals and/or metal alloys, in particular at least one of copper, copper alloys, nickel, iron nickel, aluminum, aluminum alloys, steel, stainless steel, or the like. During an operation of the semiconductor device 100 the first portion 4 of the carrier 2 may be a current carrying portion. In particular, the first portion 4 of the leadframe may be a current rail configured to carry an electric current that is to be measured by the semiconductor chip 8. In the following, the terms “first portion”, “current carrying portion” and “current rail” may be used interchangeably. In particular, the current rail 4 may be formed in one piece. The second portion 6 of the leadframe 2 may include one or multiple leads (or lead fingers or pins). In the cross sectional side view of FIG. 1, only one lead 6 is shown due to the chosen perspective. An arbitrary number of additional leads 6 may e.g., be arranged behind the illustrated lead 6.

In one example, the semiconductor chip 8 may be a sensor chip configured to sense a magnetic field generated by an electrical current flowing through the current rail 4. Based on the sensed magnetic field (or the sensed magnetic flux density of the induced magnetic field), the strength of the electrical current may be determined. In particular, the induced magnetic field may be detected without physical contact between the sensor chip 8 and the current rail 4 (e.g., galvanically isolated). In such case, the sensor chip 8 (or more particular at least one sensor element of the sensor chip 8) may at least partially overlap with the current rail 4 when viewed in the z-direction. The physical signals sensed by the sensor chip 8 may be converted into electrical signals and may be forwarded to additional components (not illustrated) via the electrical connection element 12 and the lead 4 for further processing or evaluation. In the illustrated example, the electrical connection element 12 may include a wire. In further examples, the electrical connection element 12 may include a clip, a ribbon, or the like.

The sensor chip 8 may include one or multiple sensor elements (not illustrated). In one example, the sensor chip 8 may be a differential magnetic field sensor chip including two sensor elements. For example, a sensor element of the sensor chip 8 may be a Hall sensor element, a magnetoresistive sensor element, a vertical Hall sensor element, or a fluxgate sensor element. A magnetoresistive xMR sensor element may be an AMR (Anisotropic Magneto-Resistive) sensor element, a GMR (Giant Magneto-Resistive) sensor element, or a TMR (Tunnel Magneto-Resistive) sensor element. In one example, the sensor element(s) may be arranged on the top surface of the sensor chip 8 facing away from the current rail 4. In further examples, the sensor element(s) may be arranged on a bottom surface of the sensor chip 8 facing the current rail 4.

In the illustrated example, the dielectric material 10 may include an example number of two stacked dielectric elements (or dielectric layers) 10A and 10B. For example, the dielectric elements 10A and 10B may be mechanically connected to form a one-piece dielectric. The upper dielectric element 10A may at least partially overhang the lower dielectric element 10B so that a pedestal for mounting the semiconductor chip 8 may be provided. The dielectric elements 10A and 10B may have a similar thickness or different thicknesses when measured in the z-direction. In the illustrated example, each of the dielectric elements 10A and 10B may have a thickness in an example and non-limiting range from about 50 μm to about 150 μm, typically about 100 μm.

When viewed in the z-direction, the footprint of the lower dielectric element 10B may be (in particular fully) arranged within the footprint of the upper dielectric element 10A. For example, the footprints of the dielectric elements 10A and 10B may be round, oval, elliptical, square, rectangular, polygonal, or the like. The dielectric elements 10A and 10B may be made of a same material or of different materials. Each of the dielectric elements 10A and 10B may include one or multiple of the following materials: ceramic, glass, silicone based materials, polymer based materials, or the like. In a specific example, one or both of the dielectric elements 10A and 10B may correspond to a platelet made of a dielectric material.

The encapsulation material 14 may at least partially encapsulate one or multiple components of the semiconductor device 100. In particular, the current rail 4 and the semiconductor chip 8 may be at least partially embedded in the encapsulation material 14. The encapsulation material 14 may form a housing (or package) of the encapsulated components in order to protect them against external influences, such as e.g., moisture or mechanical impact. The semiconductor device 100 may also be referred to as semiconductor package. The leads 6 may at least partially protrude out of the encapsulation material 14 such that the semiconductor chip 8 may be electrically accessible from outside of the encapsulation material 14. In a similar fashion, the current rail 4 may at least partially protrude out of the encapsulation material 14 to provide an input and an output for a measuring current.

The encapsulation material 14 may include or may be made of at least one of an epoxy, a filled epoxy, a glass fiber filled epoxy, an imide, a thermoplast, a thermoset polymer, a polymer blend, a laminate, or the like. Various techniques may be used for encapsulating components of the semiconductor device 100 with the encapsulation material 14, for example at least one of compression molding, injection molding, powder molding, liquid molding, map molding, laminating, or the like.

During an operation of the semiconductor device 100 an electrical potential of the current rail 4 may differ from an electrical potential of the semiconductor chip 8. For example, the current rail 4 may be in a high voltage domain, while the semiconductor chip 8 (and leads 6 electrically connected thereto) may be in a low voltage domain. A low voltage domain may be associated with or may be specified by an example value range from about 0V to about 20V. In this regard, typical example operating values of a low voltage domain may be about 3.3V or about 5V. A high voltage domain may be associated with or may be specified by an example value range from about 50V to about 15000V. In this regard, typical example operating values of a high voltage domain may be about 600V or about 800V or about 1200V. In a non-limiting example, an electrical potential of the semiconductor chip 8 may be about 0V, while an electrical potential of the current rail 4 may be about 1000V.

Accordingly, during an operation of the semiconductor device 100, large electrical potential differences may occur between the current rail 4 and the semiconductor chip 8. These electrical potential differences may reach values up to 1000V or more. A galvanic isolation between the current rail 4 and the semiconductor chip 8 may be provided by the dielectric material 10 arranged in between. In this context, a capacitor (or plate capacitor) may be formed, wherein each of the current rail 4 and the semiconductor chip 8 may form an electrode of the capacitor, and the dielectric material 10 may form a solid insulation between these electrodes.

Since the dielectric material 10 may have an electrical isolation capability, high electric field strengths (or high inhomogeneous electric field peaks) may occur in certain spatial regions of the semiconductor device 100. Materials located in these regions may be exposed to high electrical stress which may become particularly problematic for materials having limited insulation capabilities. The high electrical stress may result in an accelerated aging of the materials. In the course of an aging process of the semiconductor device 100, electrical treeing may occur in particular. In general, electrical treeing may occur and propagate when a dielectric material is subjected to high and divergent electrical field stress over a long period of time. Electrical treeing may typically start at corners and/or edges of a semiconductor chip and/or a leadframe of the respective semiconductor device. It may eventually result in a formation of one or multiple undesired conductive paths between the semiconductor chip and the leadframe, causing device failure in a worst scenario.

In some implementations, high electric field strengths (and thus electrical treeing in particular) may occur in a semiconductor device at positions where a current rail and/or a semiconductor chip have sharp edges and/or sharp corners. In the illustrated example of FIG. 1, a first example region 18A in which high electric field strengths may potentially occur may be located at an edge and/or corner 16A of the current rail 4. In the first region 18A of the illustrated example, a first edge of the current rail 4 may extend in the x-direction, a second edge of the current rail 4 may extend in the y-direction, and a third edge of the current rail 4 may extend in the z-direction. The three edges of the current rail 4 may meet in a corner of the current rail 4.

In the semiconductor device 100, the current rail 4 may include at least one of a rounded corner or a rounded edge 16A in the first region 18A. In this context, at least one of the first edge, the second edge, the third edge, or the corner formed by the three edges may be rounded. Due to the round shape of the corner and/or edges, high electrical field peaks may be avoided and a uniform electrical field distribution may be provided in the first region 18A. In contrast to this, conventional semiconductor devices including a current rail with sharp edges and/or corners may not achieve such uniform electrical field distribution.

In the illustrated example, the at least one rounded corner or rounded edge 16A of the current rail 4 may be arranged at the top surface of the current rail 4 facing the semiconductor chip 8. The rounded corner and/or rounded edge 16A may be adjacent to the encapsulation material 14. In particular, the rounded corner and/or rounded edge 16A and the encapsulation material 14 may have a common interface. The rounded corner and/or rounded edge 16A and the encapsulation material 14 may be in a direct physical contact. Due to the rounded shape of the corner and/or edge 16A, an electrical treeing into the encapsulation material 14 may be avoided.

A second example region 18B in which high electric field strengths may potentially occur may be located at an edge and/or a corner 16B of the semiconductor chip 8. In the second region 18B of the illustrated example, a first edge of the semiconductor chip 8 may extend in the x-direction, a second edge of the semiconductor chip 8 may extend in the y-direction, and a third edge of the semiconductor chip 8 may extend in the z-direction. The three edges of the semiconductor chip 8 may meet in the corner of the semiconductor chip 8.

In the semiconductor device 100, the semiconductor chip 8 may include at least one of a rounded corner or a rounded edge 16B in the second region 18B. In this regard, at least one of the first edge, the second edge, the third edge, or the corner formed by the three edges may be rounded. In one example, the rounded corner and/or edge 16B may be arranged at an active surface of the semiconductor chip 8. In a further example, the rounded corner and/or edge 16B may be arranged at a surface of the semiconductor chip 8 arranged opposite to an active surface. Due to the round shape of the corner and/or edges, high electrical field peaks may be avoided and a uniform electrical field distribution may be provided in the first region 18B. In contrast to this, conventional semiconductor devices including a semiconductor chip with sharp edges and/or corners may not achieve such uniform electrical field distribution.

In the illustrated example, the rounded corner and/or rounded edge 16B of the semiconductor chip 8 may be arranged at the bottom surface of the semiconductor chip 8 facing the current rail 4. The rounded corner and/or rounded edge 16B of the semiconductor chip 8 may be adjacent to the dielectric material 10. In particular, the rounded corner and/or rounded edge 16B and the dielectric material 10 may have a common interface. The materials of the rounded corner and/or rounded edge 16B and the dielectric material 10 may be in direct physical contact. Furthermore, the rounded corner and/or rounded edge 16B of the semiconductor chip 8 may be adjacent to the encapsulation material 14. In particular, the rounded corner and/or rounded edge 16B and the encapsulation material 14 may have a common interface. The materials of the rounded corner and/or rounded edge 16B and the encapsulation material 14 may be in direct physical contact. Due to the rounded shape of the rounded corner and/or rounded edge 16B, an electrical treeing into the dielectric material 10 and/or an electrical treeing into the encapsulation material 14 may be avoided. In particular, the formation of a conductive path between the semiconductor chip 8 and the current rail 4 may be avoided. Such path may e.g., extend along a common interface between the dielectric material 10 and the encapsulation material 14.

A third example region 18C in which high electric field strengths may potentially occur may be located at a further edge and/or corner 16C of the semiconductor chip 8. In the semiconductor device 100, the semiconductor chip 8 may include at least one of a rounded corner or a rounded edge 16C in the third region 18C. The rounded corner/edge 16C may be similar to the rounded corner/edge 16B such that previous comments may hold true.

The semiconductor device 200 of FIG. 2 may include some or all features of the semiconductor device 100 of FIG. 1. FIG. 2 shows various dimensions (in units of μm) for indicating sizes of device components. It is to be noted that the shown dimensions are example and in no way limiting. In other examples, the dimensions of similar components may differ, for example, by up to ±20% from the values given in FIG. 2.

The semiconductor device 200 may include similar components as previously described in connection with FIG. 1. For the sake of simplicity, leads 6 and electrical connection elements 12 of the semiconductor device 200 are not shown. The semiconductor device 200 may include a first adhesive layer 20A configured to mechanically connect the semiconductor chip 8 and the dielectric material 10. In addition, the semiconductor device 200 may include a second adhesive layer 20B configured to mechanically connect the dielectric material 10 and the current rail 4. It is noted that similar adhesive layers may be used in the previously described example of FIG. 1. In a non-limiting example, at least one of the first adhesive layer 20A and the second adhesive layer 20B may include a die attach film (DAF).

In the illustrated example, the dielectric material 10 may protrude over an outline of the current rail 4. In the example side view of FIG. 2, the right end of the dielectric material 10 may at least partially overhang the right end of the current rail 4. The current rail 4 may include at least one of a rounded corner or a rounded edge 16A in a first region 18A. The rounded corner and/or rounded edge 16A of the current rail 4 may be arranged at the top surface of the current rail 4 facing the semiconductor chip 8. Due to the rounded shape of the corner and/or edge 16A, an electrical treeing into the dielectric material 10 and/or into the encapsulation material 14 may be avoided as previously discussed in connection with FIG. 1.

For example, the current rail 4 may be stamped in a direction pointing away from the semiconductor chip 8. In the illustrated case, the current rail 4 may be stamped from top to bottom, e.g., in the negative z-direction which is indicated by an arrow. Due to such stamping of the current rail 4, the at least one rounded corner or rounded edge 16A may have been formed. In addition, the stamping of the current rail 4 may result in a burr 22 that may be arranged at an edge and/or a corner of a surface of the current rail 4 facing away from the semiconductor chip 8. A burr may be specified as a raised edge or small piece of material that may remain attached to a workpiece after a modification process, such as e.g., stamping.

In the illustrated example, the semiconductor chip 8 may include a rounded corner/edge 16B in a second region 18B and/or a rounded corner/edge in a third region 18C. The rounded corners/edges 16B, 16C and the associated regions 18B, 18C may be similar to corresponding technical features previously described in connection with FIG. 1.

In the examples of FIGS. 1 and 2, the concept of using rounded edges and/or rounded corners of device components in order to avoid high electrical field peaks in associated spatial regions has been described for the case of a magnetic current sensor device including a current rail and a sensor chip. However, it is to be noted that the concepts presented herein may also be applied to other semiconductor devices in which high electrical potential differences may occur during operation, such as e.g., gate drivers, isolated drivers, digital isolators, auxiliary power components, or the like.

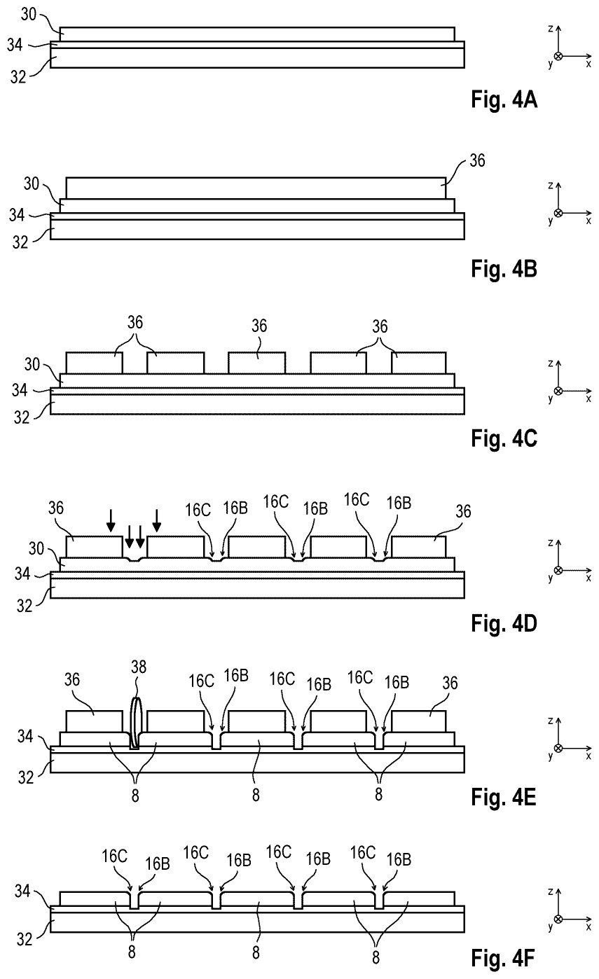

FIG. 3 illustrates a flowchart of a method for manufacturing semiconductor devices in accordance with the disclosure. The method of FIG. 3 is illustrated in a general manner in order to qualitatively specify aspects of the disclosure. The method may be used for fabricating any of the previously described semiconductor devices and may thus be read in connection with preceding figures. The method may be extended by any of the aspects described in connection with other examples discussed herein. Examples of more detailed methods for manufacturing semiconductor devices in accordance with the disclosure are shown and discussed in connection with FIGS. 4A-4F, 5A-5C, and 6A-6C.

At 24, at least one of a rounded corner or a rounded edge of at least one of a first portion of an electrically conductive carrier or a semiconductor chip may be formed. At 26, a dielectric material may be arranged over the first portion of the carrier. At 28, the semiconductor chip may be arranged over the dielectric material, wherein the dielectric material galvanically isolates the first portion of the carrier and the semiconductor chip.

FIGS. 4A-4F illustrate an example method for manufacturing one or multiple semiconductor devices in accordance with the disclosure. The method of FIGS. 4A-4F may be at least partially regarded as a more detailed version of the method of FIG. 3. In some implementations, the acts of FIGS. 4A-4F may be applied for obtaining semiconductor chips including at least one of a rounded corner or a rounded edge.

In FIG. 4A, a semiconductor wafer 30 may be arranged over a carrier 32. For example, the semiconductor wafer 30 may be made of silicon. In the illustrated example, the semiconductor wafer 30 and the carrier 32 may be mechanically connected to each other by an adhesive layer 34. In one example, the semiconductor wafer 30 may be laminated onto the carrier 32.

In FIG. 4B, a photoresist 36 may be arranged over the top surface of the semiconductor wafer 30. The photoresist 36 may (inter alia) include a resin. The photoresist 36 may be arranged substantially over the entire top surface of the semiconductor wafer 30. A thickness of the photoresist 36 may be substantially constant. In one example, the photoresist 36 may be spin-coated on the top surface of the semiconductor wafer 30.

In FIG. 4C, the photoresist 36 may be structured. In this regard, the photoresist 36 may be (in particular fully) removed at positions where the semiconductor wafer 30 is to be etched later on. By removing the photoresist 36, the semiconductor wafer 30 may become exposed at these positions. In one example, the photoresist 36 may be structured based on a suitable exposure to light and development.

In FIG. 4D, a dry etching act (or a plasma etching act) may be performed. In particular, the exposed top surfaces of the semiconductor wafer 30 may be etched, wherein at least one of rounded corners or rounded edges 16B, 16C may be formed in the top surface of the semiconductor wafer 30. An acceleration of reactive ions towards the top surface of the photoresist 36 and the exposed top surface of the semiconductor wafer 30 is indicated by arrows. During the dry etching act, grooves may be formed in the top surface of the exposed semiconductor wafer 30. In particular, dry etching may be performed all through the semiconductor wafer 30 until the top surface of the adhesive layer 34 may become exposed.

In FIG. 4E, the dry etched semiconductor wafer 30 may be singulated, wherein a plurality of semiconductor chips 8 may be obtained. In the illustrated example, the semiconductor wafer 30 may be singulated in a sawing act using a sawing blade 38. In one example, active surfaces of the obtained semiconductor chips 8 may face the carrier 32. Alternatively, or additionally, active surfaces of the semiconductor chips 8 may face away from the carrier 32. In the illustrated example, each of the semiconductor chips 8 may include at least one of rounded corners or rounded edges 16B and 16C. At least one side surface of a respective singulated semiconductor chip 8 may be dry etched.

In FIG. 4F, the photoresist 36 may be removed. In addition, the carrier 32 and the adhesive layer 34 may be removed (not illustrated). For example, an obtained semiconductor chip 8 may be similar to the semiconductor chips 8 of FIGS. 1 and 2.

The method of FIGS. 4A-4F may include additional acts which are not illustrated for the sake of simplicity. In particular, the method of FIGS. 4A-4F may be extended by the acts 26 and 28 of FIG. 3.

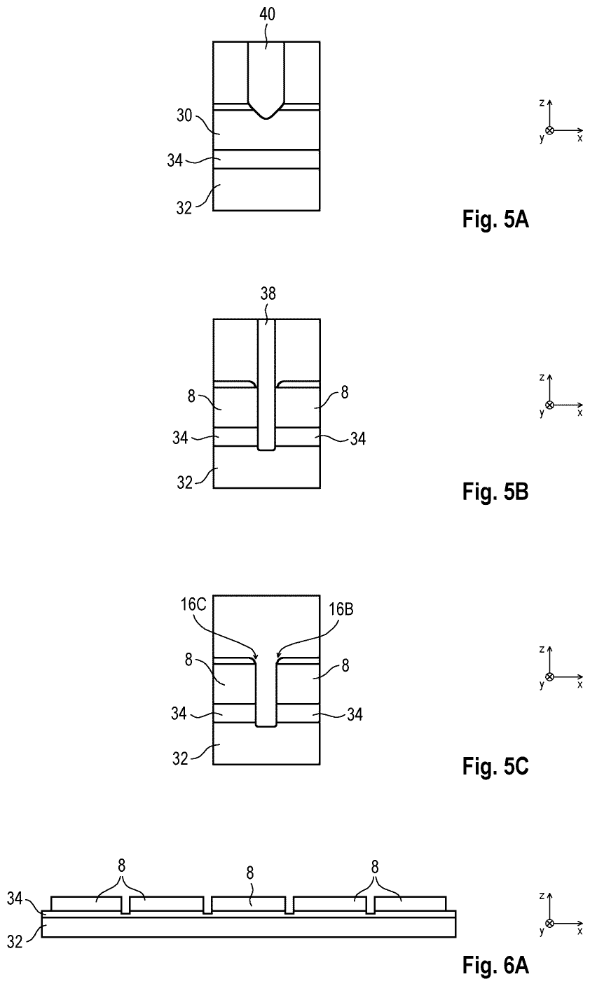

FIGS. 5A-5C illustrate an example method for manufacturing one or multiple semiconductor devices in accordance with the disclosure. The method of FIGS. 5A-5C may be at least partially regarded as a more detailed version of the method of FIG. 3. In particular, the acts of FIGS. 5A-5C may be applied for obtaining semiconductor chips including at least one of a rounded corner or a rounded edge.

In FIG. 5A, a semiconductor wafer 30 may be arranged over a carrier 32. For example, the semiconductor wafer 30 may be made of silicon. In the illustrated example, the semiconductor wafer 30 and the carrier 32 may be mechanically connected to each other by an adhesive layer 34. In a non-limiting example, the semiconductor wafer 30 may be attached onto a tape 32 using glue 34. In a further act, a chamfer cutting act may be performed. In some implementations, the top surface of the semiconductor wafer 30 may be chamfer cut using a blade 40. The blade 40 may only partially penetrate the top surface of the semiconductor wafer 30. Here, at least one of rounded corners or rounded edges 16B and 16C may be formed in the top surface of the semiconductor wafer 30.

In FIG. 5B, the chamfer cut semiconductor wafer 30 may be singulated, wherein a plurality of semiconductor chips 8 may be obtained. In the illustrated example, the chamfer cut semiconductor wafer 30 may be singulated in a sawing act using a sawing blade 38. A width of the sawing blade 38 may be smaller than a width of the previously used blade 40.

FIG. 5C illustrates the arrangement after the sawing act of FIG. 5B. Each of the obtained semiconductor chips 8 may include at least one of rounded corners or rounded edges 16B and 16C.

The method of FIGS. 5A-5C may include additional acts which are not illustrated for the sake of simplicity. In further acts, the carrier 32 and the adhesive layer 34 may be removed. For example, an obtained semiconductor chip 8 may be similar to the semiconductor chips 8 of FIGS. 1 and 2. In addition, the method of FIGS. 5A-5C may be extended by the acts 26 and 28 of FIG. 3.

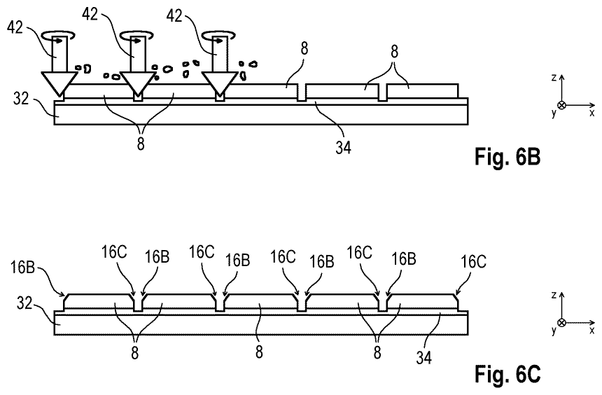

FIGS. 6A-6C illustrate an example method for manufacturing one or multiple semiconductor devices in accordance with the disclosure. The method of FIGS. 6A-6C may be at least partially regarded as a more detailed version of the method of FIG. 3. In particular, the acts of FIGS. 6A-6C may be applied for obtaining semiconductor chips including at least one of a rounded corner or a rounded edge.

In FIG. 6A, a semiconductor wafer may be arranged over a carrier 32. For example, the semiconductor wafer may be made of silicon. The semiconductor wafer and the carrier 32 may be mechanically connected to each other by an adhesive layer 34. In one example, the semiconductor wafer may be laminated onto the carrier 32. In a further act, the semiconductor wafer may be singulated, wherein a plurality of semiconductor chips 8 may be obtained. In the illustrated example, the semiconductor wafer may have been singulated in a dicing act. For example, active surfaces of the obtained semiconductor chips 8 may face the carrier 32. Alternatively, or additionally, active surfaces of the semiconductor chips 8 may face away from the carrier 32.

In FIG. 6B, a milling step may be performed. In the illustrated example, top surfaces of the semiconductor chips 8 may be milled using a milling tool 42. The milling tool 42 may include at least one beveled end section. In the illustrated example, the beveled end sections may have the shape of an arrow. The beveled end sections may rotate and may penetrate the top surfaces of the semiconductor chips 8, wherein rounded corners and/or rounded edges 16B and 16C may be formed in the top surfaces of the semiconductor chips 8.

It is to be noted that the order of the acts of FIGS. 6A and 6B may be reversed. That is, in a further example, the top surface of the semiconductor wafer may be milled first, thereby forming rounded corners and/or rounded edges 16B and 16C in the surface of the semiconductor wafer. Afterwards, the milled semiconductor wafer may be singulated, wherein semiconductor chips 8 including rounded corners and/or rounded edges may be obtained.

FIG. 6C illustrates the arrangement after the milling act of FIG. 6B has been performed. Each of the obtained semiconductor chips 8 may include at least one of a rounded corner or a rounded edge 16B and 16C.

The method of FIGS. 6A-6C may include additional acts which are not illustrated for the sake of simplicity. In further acts, the carrier 32 and the adhesive layer 34 may be removed. For example, an obtained semiconductor chip 8 may be similar to the semiconductor chips 8 of FIGS. 1 and 2. In addition, the method of FIGS. 6A-6C may be extended by the acts 26 and 28 of FIG. 3.

A further example method for manufacturing one or multiple semiconductor devices in accordance with the disclosure can be seen from previously described FIG. 2. In some implementations, the acts of such method may be applied for obtaining first portions of an electrically conductive carrier including at least one of a rounded corner or a rounded edge.

In an act, an electrically conductive material may be provided. In one example, the electrically conductive material may correspond to a material from which a leadframe is to be made, such as e.g., a flat plate or a sheet of a metal and/or a metal alloy, in particular at least one of copper, copper alloys, nickel, iron nickel, aluminum, aluminum alloys, steel, stainless steel, or the like.

In a further act, the electrically conductive material may be stamped, wherein the first portion of the carrier including the at least one of a rounded corner or a rounded edge may be formed. The first portion of the carrier may be stamped in a direction pointing away from a surface of the first portion over which a semiconductor chip is to be arranged later on. Referring back to the example of FIG. 2, a stamping direction is indicated by an arrow. In one case, a metal sheet may be stamped, wherein a current rail and at least one of a diepad and leads may be formed. Referring back to the example of FIG. 2, a stamping of the metal sheet may (inter alia) result in the current rail 4 including a rounded corner and/or rounded edge 16A located at the top surface of the current rail 4 and a burr 22 located at the bottom surface of the current rail 4.

In a further act, the stamped first portion of the carrier may be etched, wherein a burr of the electrically conductive material obtained during the stamping act may be at least partially removed. Referring back to the example of FIG. 2, the burr 22 located at the bottom surface of the current rail 4 may be at least partially removed.

In one or multiple further acts, the stamped carrier including the at least one rounded corner and/or rounded edge may be used for manufacturing a semiconductor device in accordance with the disclosure, such as e.g., the semiconductor device 200 of FIG. 2. For example, the method may be extended by the acts 26 and 28 of FIG. 3.

ASPECTS In the following, semiconductor devices in accordance with the disclosure and methods for manufacturing thereof are explained using aspects.

Aspect 1 is a semiconductor device, comprising: an electrically conductive carrier; a semiconductor chip arranged over a first portion of the carrier; and a dielectric material arranged between the first portion of the carrier and the semiconductor chip, wherein the dielectric material galvanically isolates the first portion of the carrier and the semiconductor chip, wherein at least one of the first portion of the carrier or the semiconductor chip includes at least one of a rounded corner or a rounded edge.

Aspect 2 is a semiconductor device according to Aspect 1, wherein during an operation of the semiconductor device the first portion of the carrier is a current carrying portion.

Aspect 3 is a semiconductor device according to Aspect 1 or 2, wherein during an operation of the semiconductor device the first portion of the carrier is in a high voltage domain and the semiconductor chip is in a low voltage domain.

Aspect 4 is a semiconductor device according to one of the preceding Aspects, wherein: the carrier is a leadframe, the first portion of the carrier is a current rail, and the semiconductor chip is a sensor chip configured to sense a magnetic field generated by an electrical current flowing through the current rail.

Aspect 5 is a semiconductor device according to one of the preceding Aspects, wherein at least one of a rounded corner or a rounded edge of the semiconductor chip is arranged at a surface of the semiconductor chip facing the first portion of the carrier.

Aspect 6 is a semiconductor device according to one of the preceding Aspects, wherein at least one of a rounded corner or a rounded edge of the semiconductor chip is adjacent to the dielectric material.

Aspect 7 is a semiconductor device according to one of the preceding Aspects, wherein at least one of a rounded corner or a rounded edge of the first portion of the carrier is arranged at a surface of the first portion of the carrier facing the semiconductor chip.

Aspect 8 is a semiconductor device according to one of the preceding Aspects, wherein at least one of a rounded corner or a rounded edge of the first portion of the carrier is adjacent to the dielectric material.

Aspect 9 is a semiconductor device according to one of the preceding Aspects, further comprising: an encapsulation material, wherein the first portion of the carrier and the semiconductor chip are at least partially encapsulated in the encapsulation material.

Aspect 10 is a semiconductor device according to Aspect 9, wherein at least one of a rounded corner or a rounded edge of the semiconductor chip is adjacent to the dielectric material and the encapsulation material.

Aspect 11 is a semiconductor device according to Aspect 9 or 10, wherein the dielectric material protrudes over an outline of the first portion of the carrier and at least one of a rounded corner or a rounded edge of the first portion of the carrier is adjacent to the dielectric layer and the encapsulation material.

Aspect 12 is a semiconductor device according to one of the preceding Aspects, wherein the first portion of the carrier is stamped in a direction pointing away from the semiconductor chip.

Aspect 13 is a semiconductor device according to one of the preceding Aspects, wherein the first portion of the carrier includes a burr at an edge of a surface facing away from the semiconductor chip.

Aspect 14 is a semiconductor device according to one of the preceding Aspects, wherein a side surface of the semiconductor chip is dry etched.

Aspect 15 is a method for manufacturing a semiconductor device, the method comprising: forming at least one of a rounded corner or a rounded edge of at least one of a first portion of an electrically conductive carrier or a semiconductor chip; arranging a dielectric material over the first portion of the carrier; and arranging the semiconductor chip over the dielectric material, wherein the dielectric material galvanically isolates the first portion of the carrier and the semiconductor chip.

Aspect 16 is a method according to Aspect 15, wherein forming at least one of a rounded corner or a rounded edge of the semiconductor chip comprises: dry etching a surface of a semiconductor wafer, wherein the at least one of a rounded corner or a rounded edge is formed in the surface of the semiconductor wafer, and singulating the dry etched wafer, wherein the semiconductor chip is obtained.

Aspect 17 is a method according to Aspect 15 or 16, wherein forming at least one of a rounded corner or a rounded edge of the semiconductor chip comprises: chamfer cutting a surface of a semiconductor wafer, wherein the at least one of a rounded corner or a rounded edge is formed in the surface of the semiconductor wafer, and singulating the chamfer cut semiconductor wafer, wherein the semiconductor chip is obtained.

Aspect 18 is a method according to one of Aspects 15 to 17, wherein forming at least one of a rounded corner or a rounded edge of the semiconductor chip comprises: singulating a semiconductor wafer, wherein the semiconductor chip is obtained, and milling a surface of the semiconductor chip, wherein the at least one of a rounded corner or a rounded edge in the surface of the semiconductor chip is formed.

Aspect 19 is a method according to one of Aspects 15 to 18, wherein forming at least one of a rounded corner or a rounded edge of the first portion of the carrier comprises: providing an electrically conductive material; stamping the electrically conductive material, wherein the first portion of the carrier including the at least one of a rounded corner or a rounded edge is formed, wherein the first portion of the carrier is stamped in a direction pointing away from the semiconductor chip arranged thereon.

Aspect 20 is a method according to Aspect 19, further comprising: etching the stamped first portion of the carrier, wherein a burr of the electrically conductive material obtained during stamping is at least partially removed.

While the present disclosure has been described with reference to illustrative aspects, this description is not intended to be construed in a limiting sense. Various modifications and combinations of the illustrative aspects, as well as other aspects of the disclosure, will be apparent to persons skilled in the art upon reference of the description. It is therefore intended that the appended claims encompass any such modifications or aspects.

1. A semiconductor device, comprising:
an electrically conductive carrier;
a semiconductor chip arranged over a first portion of the electrically conductive carrier; and
a dielectric material arranged between the first portion of the electrically conductive carrier and the semiconductor chip,
wherein the dielectric material galvanically isolates the first portion of the electrically conductive carrier and the semiconductor chip, and
wherein at least one of the first portion of the electrically conductive carrier or the semiconductor chip includes at least one of a rounded corner or a rounded edge.

2. The semiconductor device of claim 1, wherein during an operation of the semiconductor device the first portion of the electrically conductive carrier is a current carrying portion.

3. The semiconductor device of claim 1, wherein during an operation of the semiconductor device the first portion of the electrically conductive carrier is in a high voltage domain and the semiconductor chip is in a low voltage domain.

4. The semiconductor device of claim 1, wherein:
the electrically conductive carrier is a leadframe,
the first portion of the electrically conductive carrier is a current rail, and
the semiconductor chip is a sensor chip configured to sense a magnetic field generated by an electrical current flowing through the current rail.

5. The semiconductor device of claim 1, wherein at least one of a rounded corner or a rounded edge of the semiconductor chip is arranged at a surface of the semiconductor chip facing the first portion of the electrically conductive carrier.

6. The semiconductor device of claim 1, wherein at least one of a rounded corner or a rounded edge of the semiconductor chip is adjacent to the dielectric material.

7. The semiconductor device of claim 1, wherein at least one of a rounded corner or a rounded edge, of the first portion of the carrier is arranged at a surface of the first portion of the carrier facing the semiconductor chip.

8. The semiconductor device of claim 1, wherein at least one of a rounded corner or a rounded edge of the first portion of the electrically conductive carrier is adjacent to the dielectric material.

9. The semiconductor device of claim 1, further comprising:
an encapsulation material, wherein the first portion of the electrically conductive carrier and the semiconductor chip are at least partially encapsulated in the encapsulation material.

10. The semiconductor device of claim 9, wherein at least one of a rounded corner or a rounded edge of the semiconductor chip is adjacent to the dielectric material and the encapsulation material.

11. The semiconductor device of claim 9, wherein the dielectric material protrudes over an outline of the first portion of the electrically conductive carrier and at least one of a rounded corner or a rounded edge of the first portion of the electrically conductive carrier is adjacent to the dielectric material and the encapsulation material.

12. The semiconductor device of claim 1, wherein the first portion of the electrically conductive carrier is stamped in a direction pointing away from the semiconductor chip.

13. The semiconductor device of claim 1, wherein the first portion of the electrically conductive carrier includes a burr at an edge of a surface facing away from the semiconductor chip.

14. The semiconductor device of claim 1, wherein a side surface of the semiconductor chip is dry etched.

15. A method for manufacturing a semiconductor device, the method comprising:
forming at least one of a rounded corner or a rounded edge of at least one of a first portion of an electrically conductive carrier or a semiconductor chip;
arranging a dielectric material over the first portion of the electrically conductive carrier; and
arranging the semiconductor chip over the dielectric material, wherein the dielectric material galvanically isolates the first portion of the electrically conductive carrier and the semiconductor chip.

16. The method of claim 15, wherein forming the at least one of the rounded corner or the rounded edge of the semiconductor chip comprises:
dry etching a surface of a semiconductor wafer, wherein the at least one of the rounded corner or the rounded edge is formed in the surface of the semiconductor wafer; and
singulating the dry etched wafer.

17. The method of claim 15, wherein forming the at least one of the rounded corner or the rounded edge of the semiconductor chip comprises:
chamfer cutting a surface of a semiconductor wafer, wherein the at least one of the rounded corner or the rounded edge is formed in the surface of the semiconductor wafer; and
singulating the chamfer cut semiconductor wafer.

18. The method of claim 15, wherein forming the at least one of the rounded corner or the rounded edge of the semiconductor chip comprises:
singulating a semiconductor wafer; and
milling a surface of the semiconductor chip, wherein the at least one of the rounded corner or the rounded edge in the surface of the semiconductor chip is formed.

19. The method of claim 15, wherein forming the at least one of the rounded corner or the rounded edge of the first portion of the electrically conductive carrier comprises:
providing an electrically conductive material; and
stamping the first portion of the electrically conductive material,
wherein the first portion of the electrically conductive carrier includes the at least one of the rounded corner or the rounded edge is formed,
wherein the first portion of the electrically conductive carrier is stamped in a direction pointing away from the semiconductor chip arranged thereon.

20. The method of claim 19, further comprising:
etching the stamped first portion of the electrically conductive carrier, wherein a burr of the electrically conductive material obtained during stamping is at least partially removed.
